(19) United States
(12) Patent Application Publication
(10) Pub. No.: US 2021/0068278 A1
(43) Pub. Date: Mar. 4, 2021

(54) PROTECTION DEVICE

(71) Applicants: LITE-ON ELECTRONICS (GUANGZHOU) LIMITED, GUANGZHOU (CN); Lite-On Technology Corporation, Taipei (TW)

(72) Inventors: Yi-An Shih, Taipei (TW); Wei-Hung Hsu, Taipei (TW); Yuan-Syun Luo, Taipei (TW); Wei-Yu Hsu, Taipei (TW); Chia-Cheng Huang, Taipei (TW)

(73) Assignees: LITE-ON ELECTRONICS (GUANGZHOU) LIMITED, GUANGZHOU (CN); Lite-On Technology Corporation, Taipei (TW)

(21) Appl. No.: 16/601,493

(22) Filed: Oct. 14, 2019

(30) Foreign Application Priority Data
Aug. 29, 2019 (CN) 201910806129.4

(51) Int. Cl. H05K 5/00; H05K 1/02; H05K 7/20

(52) U.S. Cl. CPC H05K 5/0056; H05K 5/0091; H05K 7/20454; H05K 1/021

(57) ABSTRACT

A protection device including a first housing, a second housing, a power component, a protective cover and a circuit board is provided. The second housing and the first housing are assembled to each other to define an internal space. The power component is disposed on the second housing and located in the internal space. The protective cover covers the power component and is located in the internal space. The circuit board is disposed in the internal space, and the protective cover is located between the circuit board and the power component. At least one pin of the power component protrudes beyond the circuit board through the protective cover and the circuit board.

### CROSS-REFERENCE TO RELATED APPLICATION

This application claims the priority benefit of China application serial no. 201910806129.4, filed on Aug. 29, 2019. The entirety of the above-mentioned patent application is hereby incorporated by reference herein and made a part of this specification.

### BACKGROUND

### Technical Field

The invention relates to a protection device, and more particularly, relates to a protection device having better safety.

### Description of Related Art

Insulated gate bipolar transistors (IGBT) is used as a power component for AC and DC conversion in most of general inverter/motor driver products, wherein a power integrated module (PIM) of the insulated gate bipolar transistor can be further divided into Easy Pack and Econo Pack. Since an explosion often happens to a short-circuit situation of this type of power component with fuse failure, the splashed parts and sparks may cause injury to users or cause fire accident if the product is not completely sealed.

In order to solve the problem above, it is currently attempted to block a gap between a motherboard and a housing. However, in addition to the fact that parts cannot be 100% sealed due to tolerances, if materials such as white glue or rubber are used to block the gap, not only extra/additional parts and working-hour costs may be correspondingly increased, but also the difficulty of subsequent maintenance may be increased. Therefore, how to avoid the parts and sparks splashed by the power integrated module of the insulated gate bipolar transistor due to short circuit from causing injury to users or causing fire has become one of the problems to be solved by those skilled in the art.

### SUMMARY

The invention provides a protection device with protective cover covering power component for better safety.

The protection device of the invention includes a first housing, a second housing, a power component and a protective cover. The second housing and the first housing are assembled to each other to define an internal space. The power component is disposed on the second housing and located in the internal space. The protective cover covers the power component and is located in the internal space. A circuit board is disposed in the internal space, wherein the protective cover is located between the circuit board and the power component, and at least one pin of the power component protrudes beyond the circuit board through the protective cover and the circuit board.

In an embodiment of the invention, the second housing has an accommodating cavity, and the power component is disposed in the accommodating cavity.

In an embodiment of the invention, the protection device further includes a heat sink fin assembled on the second housing. The power component is above the heat sink fin, and orthographic projections of the power component and the heat sink fin mostly overlap with each other.

In an embodiment of the invention, the protective cover has at least one opening, and the pin of the power component protrudes beyond the protective cover through the opening.

In an embodiment of the invention, a gap is provided between the protective cover and the power component.

In an embodiment of the invention, the protective cover has a first side and a second side opposite to each other and a third side and a fourth side opposite to each other and connecting the first side and the second side. The third side and the fourth side are perpendicular to the first side and the second side. The first side, the second side, the third side and the fourth side surround a periphery of the power component.

In an embodiment of the invention, the protective cover has a first side and a second side opposite to each other and a third side connecting the first side and the second side. The third side is perpendicular to the first side and the second side. The first side, the second side and the third side surround a periphery of the power component and expose a side of the power component.

In an embodiment of the invention, the protection device further includes a cushioning material attached to the first side, the second side and the third side of the protective cover.

In an embodiment of the invention, the cushioning material is a sponge.

In an embodiment of the invention, a material of the protective cover is a polymeric material.

In an embodiment of the invention, the polymeric material includes polycarbonate (PC), acrylonitrile-butadiene-styrene (ABS), polymethylmethacrylate (PMMA) or a combination thereof. A thickness of the protective cover is between 1 mm and 3 mm.

In an embodiment of the invention, the polymeric material includes polyethylene terephthalate (PET), poly vinyl chloride (PVC) or a combination thereof. A thickness of the protective cover is between 0.051 mm and 3 mm.

In an embodiment of the invention, the power component includes an insulated gate bipolar transistor (IGBT), a metal oxide semiconductor field effect transistor (MOSFET) or a high electron mobility transistor (HEMT).

Based on the above, in the design of the protection device of the invention, the protective cover covers the power component, and the pins of the power component protrude beyond the circuit board through the protective cover and the circuit board. As a result, because the parts and sparks generated by the power component due to the explosion caused by short circuit can be limited within a range to prevent users from injury or prevent equipment from fire, product safety can be significantly improved.

To make the aforementioned more comprehensible, several embodiments accompanied with drawings are described in detail as follows.

### BRIEF DESCRIPTION OF THE DRAWINGS

FIG. 1A is a 3D view of a protection device according to an embodiment of the invention.

FIG. 1B is a 3D view of the protection device of FIG. 1A from another perspective.

FIG. 1C is a 3D explosion view of the protection device of FIG. 1A.

FIG. 1D is a partial cross-sectional view of the protection device of FIG. 1A.

FIG. 2A is a 3D explosion view of a protection device according to another embodiment of the invention.

FIG. 2B is a partial cross-sectional view of the protection device of FIG. 2A.

FIG. 3A is a 3D explosion view of a protection device according to another embodiment of the invention.

FIG. 3B is a partial cross-sectional view of the protection device of FIG. 3A.

FIG. 4A is a 3D explosion view of a protection device according to another embodiment of the invention.

FIG. 4B is a partial cross-sectional view of the protection device of FIG. 4A.

FIG. 4C is a 3D perspective view of a protective cover of the protection device of FIG. 4A.

### DETAILED DESCRIPTION

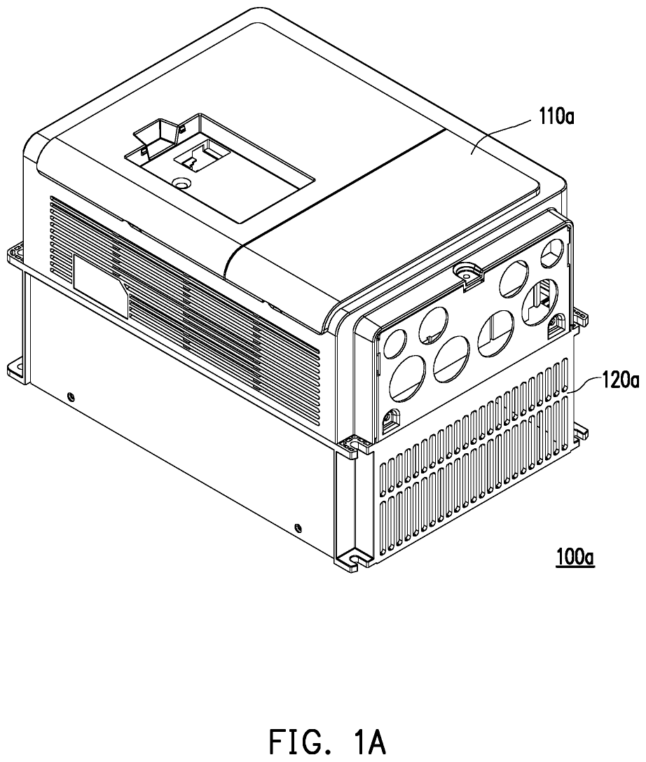

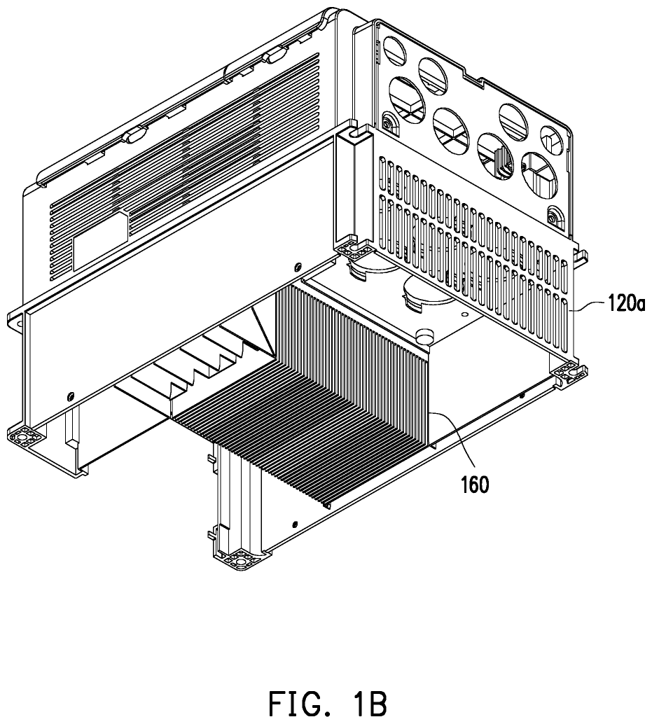

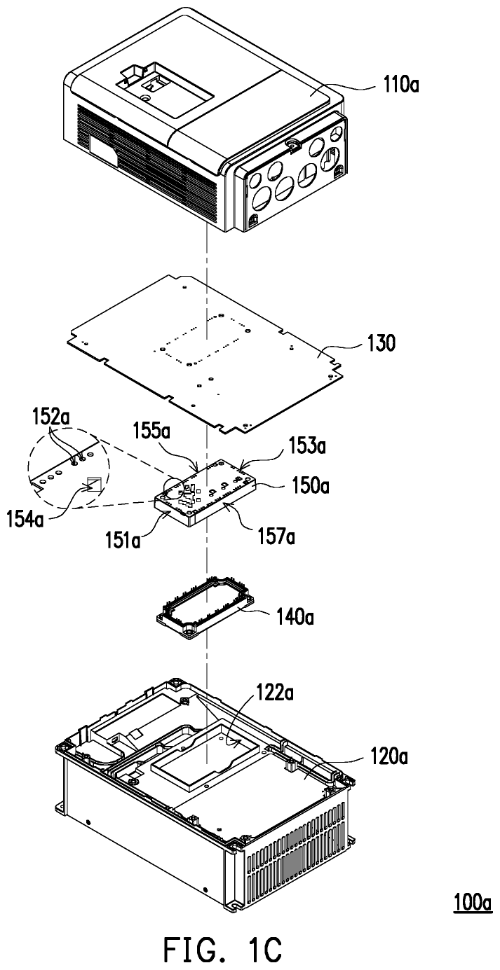

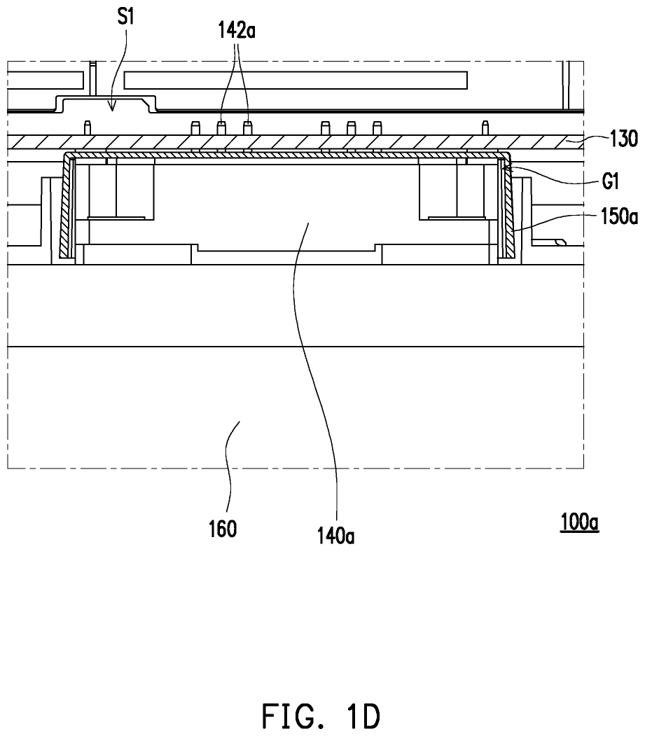

FIG. 1A is a 3D view of a protection device according to an embodiment of the invention. FIG. 1B is a 3D view of the protection device of FIG. 1A from another perspective. FIG. 1C is a 3D explosion view of the protection device of FIG. 1A. FIG. 1D is a partial cross-sectional view of the protection device of FIG. 1A. For illustrative purposes, certain components, such as the electronic components, through holes or conductive through holes are omitted from a circuit board 130 in FIG. 1C.

Referring to FIG. 1A, FIG. 1B, FIG. 1C and FIG. 1D together, a protection device 100a of the present embodiment includes a first housing 110a, a second housing 120a, a power component 140a and a protective cover 150a. The second housing 120a and the first housing 110a are assembled to each other to define an internal space S1. The power component 140a is disposed on the second housing 120a and located in the internal space S1. The protective cover 150a covers the power component 140a and is located in the internal space S1. At least one pin (a plurality of pins 142a are schematically illustrated) of the power component 140a protrudes through the protective cover 150a to extend outside the protective cover 150a.

In detail, the first housing 110a and the second housing 120a may be regarded as an upper housing and a lower housing respectively, wherein the first housing 110a is assembled on the second housing 120a. The second housing 120a has an accommodating cavity 122a, and the power component 140a is disposed in the accommodating cavity 122a. The power component 140a is, for example, an insulated gate bipolar transistor (IGBT), a metal oxide semiconductor field effect transistor (MOSFET), a high electron mobility transistor (HEMT) or other suitable power components. Herein, the power component 140a is exemplified by Econo Pack of the power integrated module (PIM) of the IGBT that has a rated voltage of, for example, 200V, but not limited thereto.

In addition, the protection device 100a of the present embodiment further includes a circuit board 130, wherein the circuit board 130 is disposed in the internal space S1, and the protective cover 150a is located between the circuit board 130 and the power component 140a. The pins 142a of the power component 140a protrude beyond the circuit board 130 through the protective cover 150a and the circuit board 130. In this case, the pins 142a of the power component 140a can be electrically connected to the circuit board 130.

In particular, the protective cover 150a of the present embodiment covers the power component 140a, wherein a gap G1 is provided between the protective cover 150a and the power component 140a. More specifically, the protective cover 150a has a first side 151a and a second side 153a opposite to each other, and a third side 155a and a fourth side 157a opposite to each other and connecting the first side 151a and the second side 153a. The third side 155a and the fourth side 157a are perpendicular to the first side 151a and the second side 153a. The first side 151a, the second side 153a, the third side 155a and the fourth side 157a surround a periphery of the power component 140a. In other words, the protective cover 150a of the present embodiment is a mask that completely covers upper and surrounding surfaces of the power component 140a. Further, the protective cover 150a has at least one opening (a plurality of openings 152a are schematically illustrated in FIG. 1C), and the pins 142a of the power component 140a protrude beyond the circuit board 130 through the openings 152a and the circuit board 130. In addition, the protective cover 150a further includes at least one broken hole (a plurality of broken holes 154a are schematically illustrated in FIG. 1C), which is used to avoid pins (not illustrated) of a dual inline-pin package (DIP) on the circuit board 130 or other functions/types of components, modules or connecting wires/fragments provided on the circuit board 130 rather than limit the scope of the invention.

Herein, a material of the protective cover 150a is a polymeric material, wherein the polymeric material is, for example, polycarbonate (PC), acrylonitrile-butadiene-styrene (ABS), polymethylmethacrylate (PMMA) or a combination thereof. That is to say, the material of the protective cover 150a is plastic, wherein a thickness of the protective cover 150a is, for example, between 1 mm and 3 mm, and more preferably, 1.5 mm.

Moreover, the protection device 100a further includes a heat sink fin 160, wherein the heat sink fin 160 is assembled on the second housing 120a to dissipate heat from the power component 140a. Herein, the power component 140a is above the heat sink fin 160, and orthographic projections of the power component 140a and the heat sink fin 160 mostly overlap with each other. Also, the power component 140a can directly contact the heat sink fin 160, but is not limited thereto.

In the design of the protection device 100a of the present embodiment, the protective cover 150a covers the power component 140a, and the pins 142a of the power component 140a protrude beyond the circuit board 130 through the protective cover 150a and the circuit board 130. Therefore, when parts and sparks are generated due to the explosion caused by short circuit in the power component 140a, the generated parts and sparks may be splashed along the gap G1 between the protective cover 150a and the power component 140a and toward the heat sink fin 160. In other words, since the generated parts and sparks may be splashed along an inner edge of the protective cover 150a towards the surrounding sides and further drained down to the heat sink fin 160, the impact force can be reduced and a range of the splashed sparks can be effectively regulated/limited. In brief, because the protection device 100a has the design of the protective cover 150a, the parts and sparks generated by the power component 140a due to the explosion caused by short circuit can be limited within a range to prevent users from injury or prevent equipment from fire, product safety can be significantly improved. In addition, because an assembling and disassembling method for the protective cover 150a covering the power element 140a is simple, the working hour for assembly can be reduced and the difficulty of maintenance can be reduced to thereby increase product competitiveness.

It should be noted that the reference numerals and a part of the contents in the previous embodiment are used in the following embodiments, in which identical reference numerals indicate identical or similar components, and repeated description of the same technical contents is omitted. For a detailed description of the omitted parts, reference can be found in the previous embodiment, and no repeated description is contained in the following embodiments.

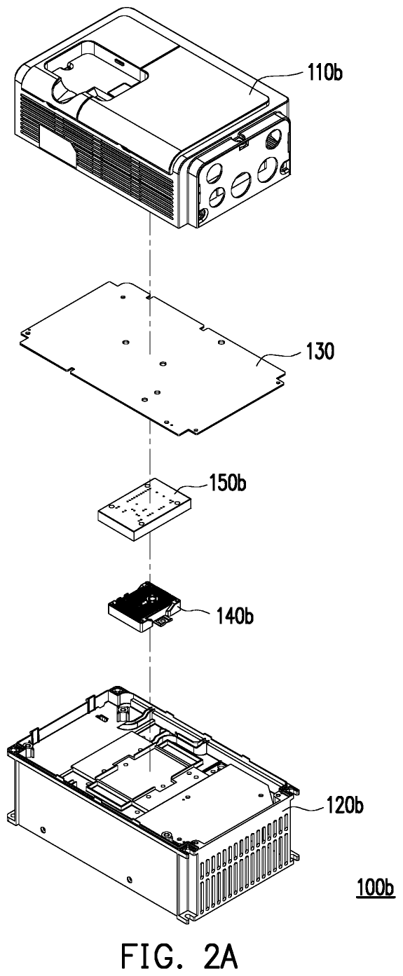

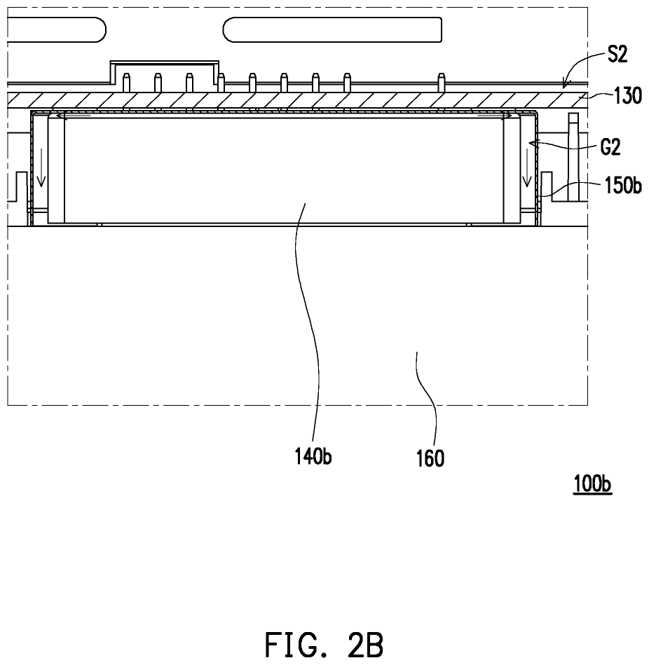

FIG. 2A is a 3D explosion view of a protection device according to another embodiment of the invention. FIG. 2B is a partial cross-sectional view of the protection device of FIG. 2A. For illustrative purposes, certain components, such as the electronic components, through holes or conductive through holes are omitted from the circuit board 130 in FIG. 2A.

Referring to FIG. 1C, FIG. 1D, FIG. 2A and FIG. 2B together, a protection device 100b of the present embodiment is similar to the protection device 100a of FIG. 1C, but differs in that, a power component 140b located in an internal space S2 defined by a first housing 110b and a second housing 120b in the present embodiment is specifically exemplified by Easy Pack of the power integrated module (PIM) of the IGBT that has a rated voltage of, for example, 200V, but not limited thereto. Furthermore, a material of the protective cover 150b of the present embodiment is a polymeric material, wherein the polymeric material includes polyethylene terephthalate (PET), poly vinyl chloride (PVC) or a combination thereof. That is to say, the material of the protective cover 150b is Mylar, wherein a thickness of the protective cover 150b is, for example, between 0.051 mm and 3 mm, and more preferably, 0.23 mm.

Therefore, when parts and sparks are generated due to the explosion caused by short circuit in the power component 140b, the generated parts and sparks may be splashed along arrow directions in FIG. 2B from a gap G2 between the protective cover 150b and the power component 140b toward the heat sink fin 160 below. Accordingly, the impact force can be reduced and a range of the splashed sparks can be effectively regulated/limited. In brief, because the protection device 100b has the design of the protective cover 150b, the parts and sparks generated by the power component 140b due to the explosion caused by short circuit can be limited within a range to prevent users from injury or prevent equipment from fire, product safety can be significantly improved.

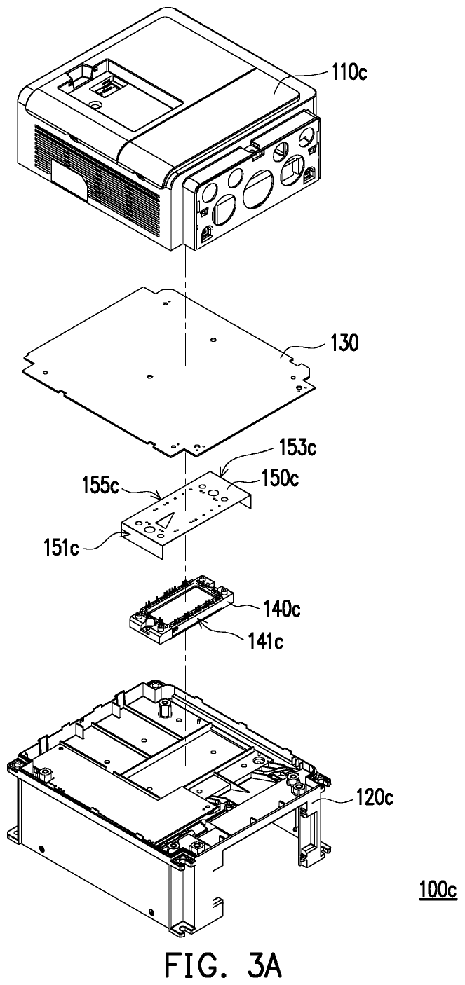

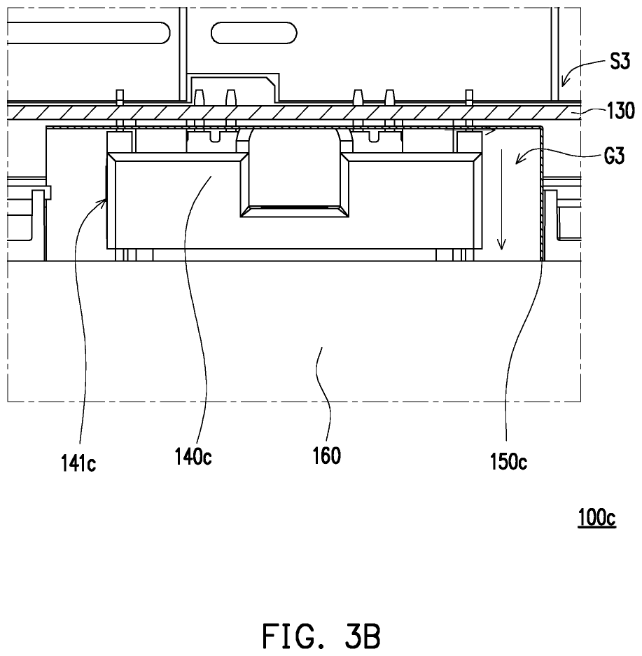

FIG. 3A is a 3D explosion view of a protection device according to another embodiment of the invention. FIG. 3B is a partial cross-sectional view of the protection device of FIG. 3A. For illustrative purposes, certain components, such as the electronic components, through holes or conductive through holes are omitted from the circuit board 130 in FIG. 3A.

Referring to FIG. 1C, FIG. 1D, FIG. 3A and FIG. 3B together, a protection device 100c of the present embodiment is similar to the protection device 100a of FIG. 1C, but differs in that, a power component 140c located in an internal space S3 defined by a first housing 110c and a second housing 120c in the present embodiment is specifically exemplified by Econo Pack of the power integrated module (PIM) of the IGBT, but not limited thereto.

In addition, a protective cover 150c of the present embodiment has a first side 151c and a second side 153c opposite to each other and a third side 155c connecting the first side 151c and the second side 153c. The third side 155c is perpendicular to the first side 151c and the second side 153c. The first side 151c, the second side 153c and the third side 155c surround a periphery of the power component 140c and expose a side 141c of the power component 140c. Herein, the side 141c of the power component 140c directly faces a wiring board (not illustrated) locked on the second housing 120c.

Therefore, when the parts and sparks are generated due to the explosion caused by short circuit in the power component 140c, the generated parts and sparks may be splashed along an arrow direction in FIG. 3B from a gap G3 between the protective cover 150c and the power component 140c toward the heat sink fin 160, the wiring board (not illustrated) and a rubber plug (not illustrated) below. Accordingly, the impact force can be blocked effectively and a range of the splashed sparks can be effectively regulated/limited. In brief, because the protection device 100c has the design of the protective cover 150c, the parts and sparks generated by the power component 140c due to the explosion caused by short circuit can be limited within a range to prevent users from injury or prevent equipment from fire, product safety can be significantly improved.

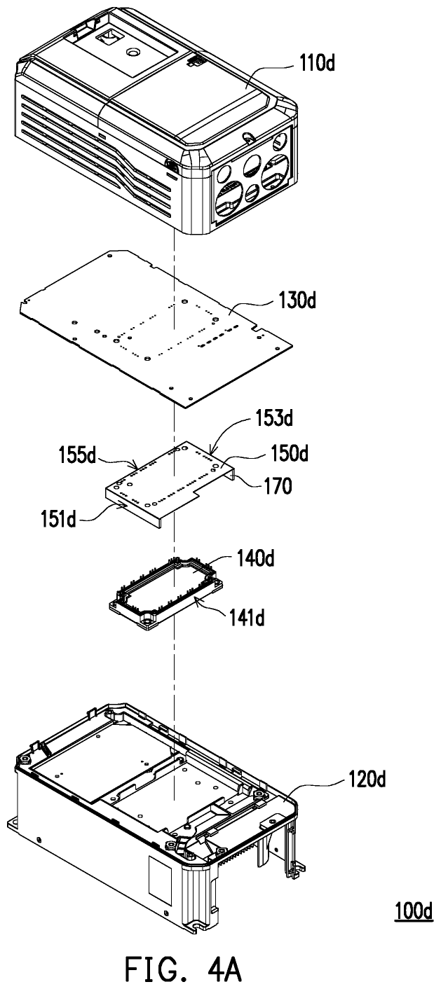

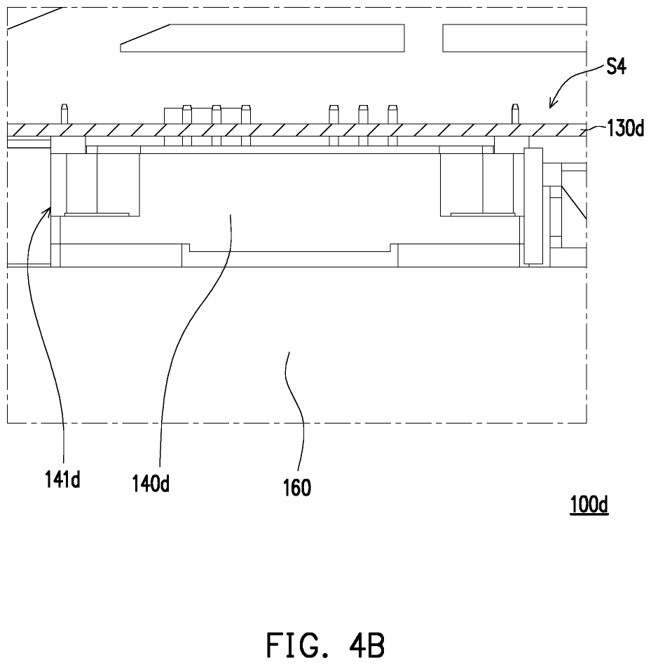

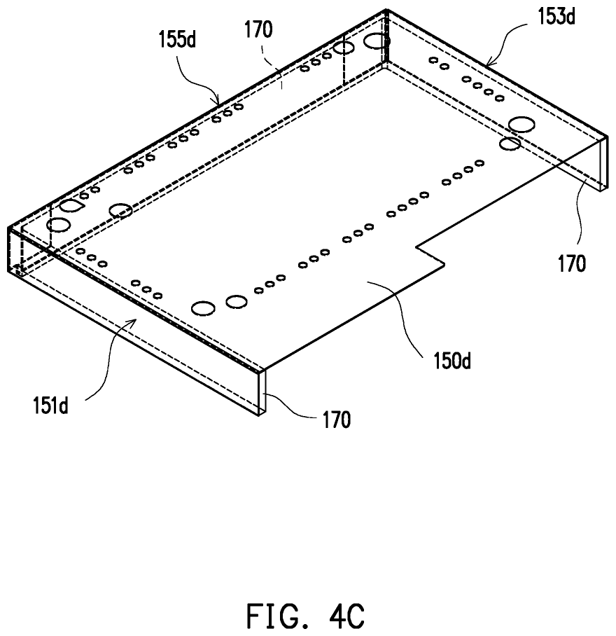

FIG. 4A is a 3D explosion view of a protection device according to another embodiment of the invention. FIG. 4B is a partial cross-sectional view of the protection device of FIG. 4A. FIG. 4C is a 3D perspective view of a protective cover of the protection device of FIG. 4A. Referring to FIG. 1C, FIG. 4A, FIG. 4B and FIG. 4C together, a protection device 100d of the present embodiment is similar to the protection device 100a of FIG. 1C, but differs in that, the protection device 100d includes a first housing 110d, a second housing 120d, a power component 140d, a protective cover 150d and a circuit board 130d, wherein the circuit board 130d, the power component 140d and the protective cover 150d are located in an internal space S4 defined by the first housing 110d and the second housing 120d.

In addition, the protective cover 150d of the present embodiment has a first side 151d and a second side 153d opposite to each other and a third side 155d connecting the first side 151d and the second side 153d, wherein the third side 155d is perpendicular to the first side 151d and the second side 153d. The first side 151d, the second side 153d and the third side 155d surround a periphery of the power component 140d and expose a side 141d of the power component 140d. Herein, the side 141d of the power component 140d directly faces a wiring board (not illustrated) locked on the second housing 120d.

In addition, the protection device 100d of the present embodiment further includes a cushioning material 170, which is attached to the first side 151d, the second side 153d and the third side 155d of the protective cover 150d. Herein, the cushioning material 170 is a sponge or other substitute having the same material characteristics to effectively absorb the impact force of the parts and sparks splashed by the power component 140d due to the explosion caused by short circuit.

It should be noted that, in the embodiment not shown, a material of the protective cover can be selected according to the power of the power component. For instance, when the power is greater than 20 KW, a thicker plastic can be adopted as the material of the protective cover. Conversely, when the power is less than 20 KW, a thinner Mylar can be adopted as the material of the protective cover. That is, persons skilled in the art can adaptively change the material and a structural design of the protective cover according to different power requirements. Meanwhile, according to the size of the power component, the protective cover can also be correspondingly designed to have a closed covering mode with four edges, or to have an open covering mode with three edges and accompanying with at least one cushioning material. The invention is not limited in this regard.

In summary, in the design of the protection device of the invention, the protective cover covers the power component, and the pins of the power component protrude through and beyond the protective cover. As a result, because the parts and sparks generated by the power component due to the explosion caused by short circuit can be limited within a range to prevent users from injury or prevent equipment from fire, product safety can be significantly improved. Moreover, because the protective cover of the invention can be shared by power components in different power ranges to provide advantages including simple assembly method, low cost, and low working hour, the costs can be effectively reduced and product competitiveness can be increased.

Although the invention has been described with reference to the above embodiments, it will be apparent to one of ordinary skill in the art that modifications to the described embodiments may be made without departing from the spirit of the invention. Accordingly, the scope of the invention will be defined by the attached claims and not by the above detailed descriptions.

1. A protection device, comprising:
a first housing;
a second housing assembled to the first housing to define an internal space;
a power component disposed on the second housing and located in the internal space;
a protective cover covering the power component and located in the internal space, wherein the power component and the protective cover are sealed in the first housing and the second housing; and
a circuit board disposed in the internal space, wherein the protective cover is located between the circuit board and the power component, the circuit board is attached to the protective cover, and at least one pin of the power component protrudes beyond the circuit board through the protective cover and the circuit board.

2. The protection device according to claim 1, wherein the second housing has an accommodating cavity, and the power component is disposed in the accommodating cavity.

3. The protection device of claim 2, further comprising:
a heat sink fin assembled on the second housing, wherein the power component is above the heat sink fin, and orthographic projections of the power component and the heat sink fin mostly overlap with each other.

4. The protection device according to claim 1, wherein the protective cover has at least one opening, and the at least one pin of the power component protrudes beyond the protective cover through the at least one opening.

5. The protection device according to claim 1, wherein a gap is provided between the protective cover and the power component.

6. The protection device according to claim 1, wherein the protective cover has a first side and a second side opposite to each other, and a third side and a fourth side opposite to each other and connecting the first side and the second side, the third side and the fourth side are perpendicular to the first side and the second side, and the first side, the second side, the third side and the fourth side surround a periphery of the power component.

7. The protection device according to claim 1, wherein the protective cover has a first side and a second side opposite to each other, and a third side connecting the first side and the second side, the third side is perpendicular to the first side and the second side, and the first side, the second side and the third side surround a periphery of the power component and expose a side of the power component.

8. The protection device of claim 7, further comprising:
a cushioning material attached to the first side, the second side and the third side of the protective cover.

9. The protection device according to claim 8, wherein the cushioning material is a sponge.

10. The protection device according to claim 1, wherein a material of the protective cover is a polymeric material.

11. The protection device according to claim 10, wherein the polymeric material comprises polycarbonate, acrylonitrile-butadiene-styrene, polymethylmethacrylate or a combination thereof, and a thickness of the protective cover is between 1 mm and 3 mm.

12. The protection device according to claim 10, wherein the polymeric material comprises polyethylene terephthalate, poly vinyl chloride or a combination thereof, and a thickness of the protective cover is between 0.051 mm and 3 mm.

13. The protection device according to claim 1, wherein the power component comprises an insulated gate bipolar transistor, a metal oxide semiconductor field effect transistor or a high electron mobility transistor.
